(19) United States
(12) Patent Application Publication
(10) Pub. No.: US 2005/0199372 A1
(43) Pub. Date: Sep. 15, 2005

(54) Cold plate and method of making the same

(76) Inventors: James T. Frazer, Big Lake, MN (US); Terrance L. Morri, Shoreview, MN (US)

Correspondence Address: DORSEY & WHITNEY LLP;INTELLECTUAL PROPERTY DEPARTMENT, 50 SOUTH SIXTH STREET, MINNEAPOLIS, MN, 55402-1498, US

(21) Appl. No.: 11/075,362

(22) Filed: Mar. 8, 2005

Related U.S. Application Data
(60) Provisional application No. 60/551,407, filed on Mar. 8, 2004.

(51) Int. Cl. H05K 7/20

(52) U.S. Cl. 165/80.4; 165/170; 361/699

(57) ABSTRACT

A cold plate having a base member and a cover member connected thereto by friction stir welding and one or more fins or flow channels machined into the base and/or the cover member. The invention also relates to a method of making a cold plate including providing a base member and a cover member, machining one or more fins or flow channels in the base and/or cover members and connecting the base and cover members via friction stir welding.

### BACKGROUND OF THE INVENTION

1. Field of the Invention

The present invention relates generally to a cold plate for cooling electronic components such as computer chips and other components, circuit boards and the like and more specifically to a cold plate construction which improves the heat dissipation and efficiency of the cold plate. The invention also relates to a method of making the cold plate of the present invention.

2. Description of the Prior Art

Electronic components mounted on circuit boards and computer chips and other computer components generate varying levels of heat which must be dissipated during operation. If left unchecked, such components can overheat, thereby adversely affecting the performance of such components and in some cases, causing them to fail. Accordingly, a necessary feature of virtually all electronic, computer, microprocessor, circuit board, disc drive assemblies and the like is a heat dissipation or removal feature. As the density of memory and the processing speed of computing systems increases and the components become smaller and smaller, heat dissipation becomes an increasingly important design factor.

In some smaller electronic systems or in some older systems, the components can be satisfactorily cooled by air movers in the form of fans. However, with current demand for faster and smaller “solid state” circuitry, which runs much hotter than earlier systems, and with large multiprocessor systems and multidisc drive systems used in dedicated computer rooms, cooling by airflow is often not an option. This is due to the inefficiencies of air cooling, acoustic noise resulting from the use of multiple fans and office environmental issues, or a combination of the above.

A further cooling system that has been previously used to cool electronic components has been what is commonly referred to as a cold plate. Conventional cold plates typically comprise a relatively flat, thermally conductive body formed with a component engagement or cooling surface that conforms to the surface configuration of the circuit board and an internal cooling channel to circulate cooling fluid. Circulation of this cooling fluid cools the engagement surface which draws heat away from the electronic components mounted on or in close proximity to that surface.

In a conventional cold plate configuration, a pair of plates are provided with one plate having a cavity or recessed area throughout its central area. One or more layers of preformed or corrugated fin stock is placed in the cavity, with brazing foil positioned between layers of the fin stock and between the fin stock and the plates. The other plate is then connected with the cavity plate around its edges by brazing.

A principal issue with the above-described cold plate construction is that the high temperature (1050° F.) required for the vacuum brazing process generally weakens the base metal characteristics. For example, when aluminum alloys, a common base element in cold plates, is heated to this temperature, the alloys go to a TO condition. Such condition requires a heat treatment to regain some of the structural strength. Further, because the individual layers of fin stock within the cavity are brazed together, there is the potential for the brazing solder to clog the fins and restrict liquid flow through the core. Still further, brazing requires many pre-brazing steps and is restricted to vacuum furnaces, thereby increasing the processing and manufacturing costs.

A still further limitation of current cold plates, and in particular, a cold plate construction utilizing conventional fin stock as described above, is the lack of efficiency anticipating or removing heat from the electronic components in the areas where such heat dissipation or removal is most needed. Electronic components such as those on a circuit board or as part of a multiprocessor or multidisc drive system are seldomly uniformly arranged on or near the cooling surface of a cold plate in such a way that maximizes the heat removal ability of the cold plate. Thus, the efficiency of cold plates of the type described above is limited.

Accordingly, there is a need in the art for an improved cold plate and method of making the same, and in particular, an improved cold plate which eliminates or minimizes the various limitations of existing cold plates. There is also a need for improving the efficiency of cold plate design to maximize the heat dissipation or heat removal ability in the areas where the electronic components are mounted and thus is needed most.

### SUMMARY OF THE INVENTION

The present invention relates to a cold plate construction and a method for making the same which overcomes the limitations in the prior art and significantly improves the heat dissipation or removal ability of the cold plate, and thus significantly improves the efficiency of such cold plate.

In accordance with the present invention, a cold plate is constructed of two basic components: a first component or plate in the form of a base or fin/baffle plate which is machined from a base block and a second component or plate in the form of a cover plate. In one embodiment, a cavity having a plurality of heat transfer fins or cooling fluid channels are machined into the base plate via a machining, milling or other process. The second component is then secured to the top of the base plate so that the inner surface of the second component is substantially engaged with the top of the fins or areas between the channels. The two components are then connected together in the area around the cavity through a friction stir welding process or other connection technique. In other embodiments, heat transfer fins or cooling channels may also be formed into the cover plate prior to connection of the cover to the base.

In a further embodiment, a pair of opposing base plates are provided and a plurality of elongated channels and fins are machined into the base plates with a “T” slot cutter so that the open channels face one another. A T-shaped filler member or cover plate is then inserted between the ends of the machined fins and the T-shaped member is connected with the respective base members by a connecting process such as friction stir welding. This cold plate configuration provides a pair of back-to-back cold plates, having particular applicability for cooling the edges of circuit boards or the like.

In a still further embodiment, a plurality of fins and baffles are machined into a base plate in a configuration which directs the cooling fluid to, and causes the cooling fluid to flow to, the areas of the cooling plate where cooling is most needed in order to maximize the ability of the cooling fluid to remove heat from the cold plate in the area of the components as much as possible.

Accordingly, one feature of the process of making a cold plate in accordance with the present invention is to (a) provide a first plate component such as a base block, (b) machine a plurality of fins and/or channels in such block and (c) connect a second plate component such as a cover to the base block via friction stir welding.

A further feature of the cold plate design and manufacturing technique of the present invention is to enable a cold plate to be custom manufactured for a specific cooling application. This involves the steps of (a) determining the location of the electronic components relative to the cold plate, (b) designing the existence of fins or channels in the base plate so as to maximize the ability of the cold plate to cool the plate in the areas where the electronic components are mounted, (c) machining the fins or channels into the base plate in the area determined and (d) connecting the cover plate to the base plate by friction stir welding or the like.

Accordingly, it is an object of the present invention to provide a cold plate which is capable of being designed to significantly increase the heat removal efficiency of that cold plate in areas where the electronic components are mounted.

Another object of the present invention is to provide a cold plate and a method for making the same which overcomes the limitations in the prior art.

These and other objects of the present invention will become apparent reference to the drawings, the description of the preferred embodiment and the appended claims.

### DESCRIPTION OF THE DRAWINGS

FIG. 1 is an isometric view showing application of a friction stir welding connection technique to a seam between two members.

FIG. 2 is an elevational view showing application of a friction stir welding connection technique to a lap joint between two members.

FIG. 3 is an isometric view of a base block for a first embodiment in accordance with the present invention.

FIG. 4 is an isometric, fragmentary view showing the base block of FIG. 3 after machining and with the cover plate separated from the base.

FIG. 5 is an isometric, fragmentary enlarged view of one end of the cold plate embodiment of FIG. 4.

FIG. 6 is a view, partially in section, as viewed along the section line 6-6 of FIG. 4, with the cover plate connected.

FIG. 7 is an unmachined base block for a further cold plate embodiment.

FIG. 8 is an isometric, fragmentary view of the cold plate embodiment of FIG. 7 with the base block machined.

FIG. 9 is an isometric, fragmentary, enlarged view of a portion of the cold plate embodiment of FIG. 8.

FIG. 10 is comprised of FIGS. 10A and 10B, with FIG. 10A being a view, partially in section, as viewed along the section line 10A-10A of FIG. 8 with the cover separated from the base and with FIG. 10B showing the cover connected to the base.

FIG. 11 is an isometric view of a further embodiment of a cold plate configuration in accordance with the present invention.

FIG. 12 is an isometric, fragmentary, enlarged view of a portion of the cold plate embodiment of FIG. 11.

FIG. 13 is a further isometric, fragmentary, enlarged view of the cold plate embodiment of FIG. 11.

FIG. 14 is an isometric, fragmentary, enlarged view of the cold plate embodiment of FIG. 11 showing such cold plate as used with a pair of customer circuit boards.

FIG. 15 is a view, partially in section, as viewed along the section line 15-15 of FIG. 12, with the left-hand cooling rib showing a connected cover plate and the right-hand cooling rib showing a cover plate prior to insertion and connection.

FIG. 16 is a further isometric, fragmentary, enlarged view of the cold plate of FIG. 11 showing a cooling rib with the T-shaped cover plate installed.

FIG. 17 is an isometric view of a further embodiment of a cold plate in accordance with the present invention.

FIG. 18 is a view, partially in section, as viewed along the section line 18-18 of FIG. 17.

FIG. 19 is an enlarged view, partially in section, of a portion of the embodiment of FIG. 17 in the process of being made.

FIG. 20 is an enlarged view, partially in section, of a portion of the embodiment of FIG. 17 with the cover secured to the base.

FIG. 21 is an isometric view of a further embodiment of a cold plate in accordance with the present invention.

FIG. 22 is a view, partially in section, as viewed along the section line 22-22 of FIG. 21.

FIG. 23 is an enlarged view, partially in section, of a portion of the embodiment of FIG. 21 in the process of being made.

FIG. 24 is an enlarged view, partially in section, of a portion of the embodiment of FIG. 21 with the cover secured to the base.

FIG. 25 is a plan view, partially in section, of a further embodiment of a cold plate in accordance with the present invention.

FIG. 26 is a view, partially in section, as viewed along the section line 26-26 of FIG. 25.

FIG. 27 is an enlarged view, of one of the cold plate assemblies of FIG. 26.

FIG. 28 is an elevational plan view, partially in section, of a further embodiment of a cold plate in accordance with the present invention.

FIG. 29 is a view, partially in section, as viewed along the section line 29-29 of FIG. 28.

FIG. 30 is an elevational plan view, partially in section, of a further embodiment of a cold plate in accordance with the present invention.

FIG. 31 is a view, partially in section, as viewed along the section line 31-31 of FIG. 30.

FIG. 32 is an elevational plan view, partially in section, of a further embodiment of a cold plate in accordance with the present invention.

FIG. 33 is a view, partially in section, as viewed along the section line 33-33 of FIG. 32.

FIG. 34 is an elevational plan view, partially in section, of a further embodiment of a cold plate in accordance with the present invention.

FIG. 35 is a view, partially in section, as viewed along the section line 35-35 of FIG. 34.

FIG. 36 is a cross-sectional view of a further embodiment of the cold plate of the present invention.

FIG. 37 is a further embodiment of a cold plate in accordance with the present invention prior to connection of the cover and base plates.

FIG. 38 is a cross-sectional view of the cold plate of FIG. 37, with the cover and base plates connected to one another.

FIG. 39 is an elevational plan view of a flow channel assembly formed in accordance with the present invention.

FIG. 40 is a view, partially in section, as viewed along the section line 40-40 of FIG. 39.

### DESCRIPTION OF THE PREFERRED EMBODIMENT

In general, the present invention relates to a cold plate and more specifically, to a cold plate for cooling circuit boards and various electronic components in which a first plate member such as a base member is machined from a single base block and in which a second plate member such as a cover plate is connected with the machined base block via a variety of connection techniques. The connection technique of the preferred embodiment is a technique referred to as friction stir welding (FSW).

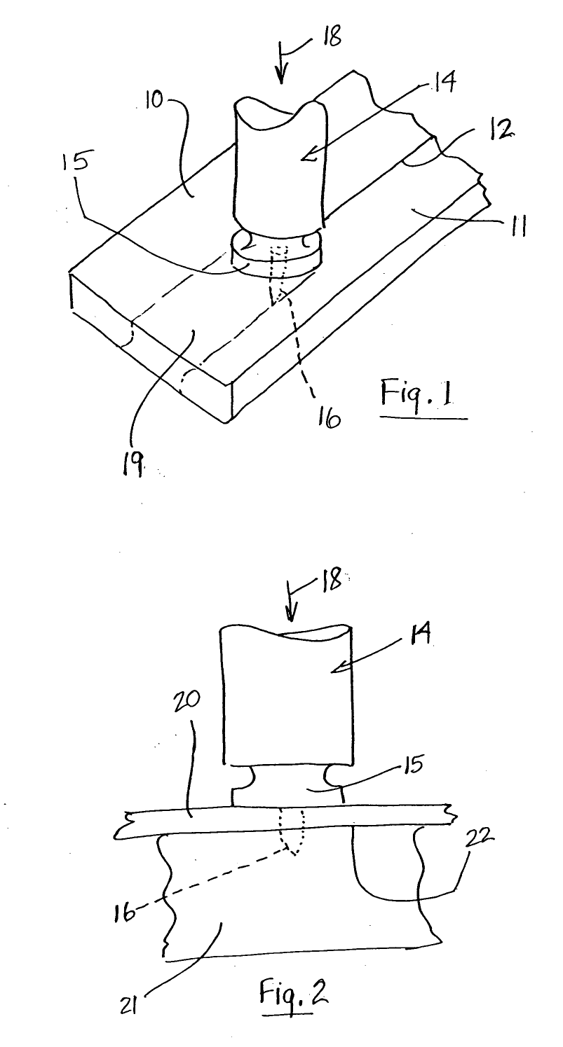

The process of friction stir welding is illustrated in FIGS. 1 and 2. In FIG. 1, two pieces of material 10 and 11 are joined together along a butt seam 12 by a friction stir welding tool 14. The tool 14 comprises, among other things, a rotating head 15 and a probe 16. During operation, the tool head 15 is rotated at high speed and a downward force 18 is maintained on the tool to maintain registered contact between the bottom of the head 15 and the top surface of the members 10 and 11. Because of the high rotational speed of the tool head 15 against the parts 10 and 11, heat is generated. This heat is sufficient to cause the materials to soften without reaching a melting point and allows the probe 16 to traverse along the seam 12. As the tool moves along the seam 12, the material in front of the probe 16 is plasticized by the frictional heat and displaced to the back of the probe. At this point, the material cools to form a solid state, full penetration web 19.

FIG. 2 shows utilization of friction stir welding to join two parts 20 and 21 along a lap joint 22. In this application, one of the parts 20 must be thin enough relative to the length of the probe 16 so that the probe can pass through the part 20 and plasticize a portion of a part 21 during the bonding process. In general, depending on the material, the member 20 should have a thickness no greater than about 1 to 1- 1/2 inches. The types of material that can be friction stir welded, among possible others, include aluminum, magnesium, copper, titanium, various steels, nickel, and alloys of these metals.

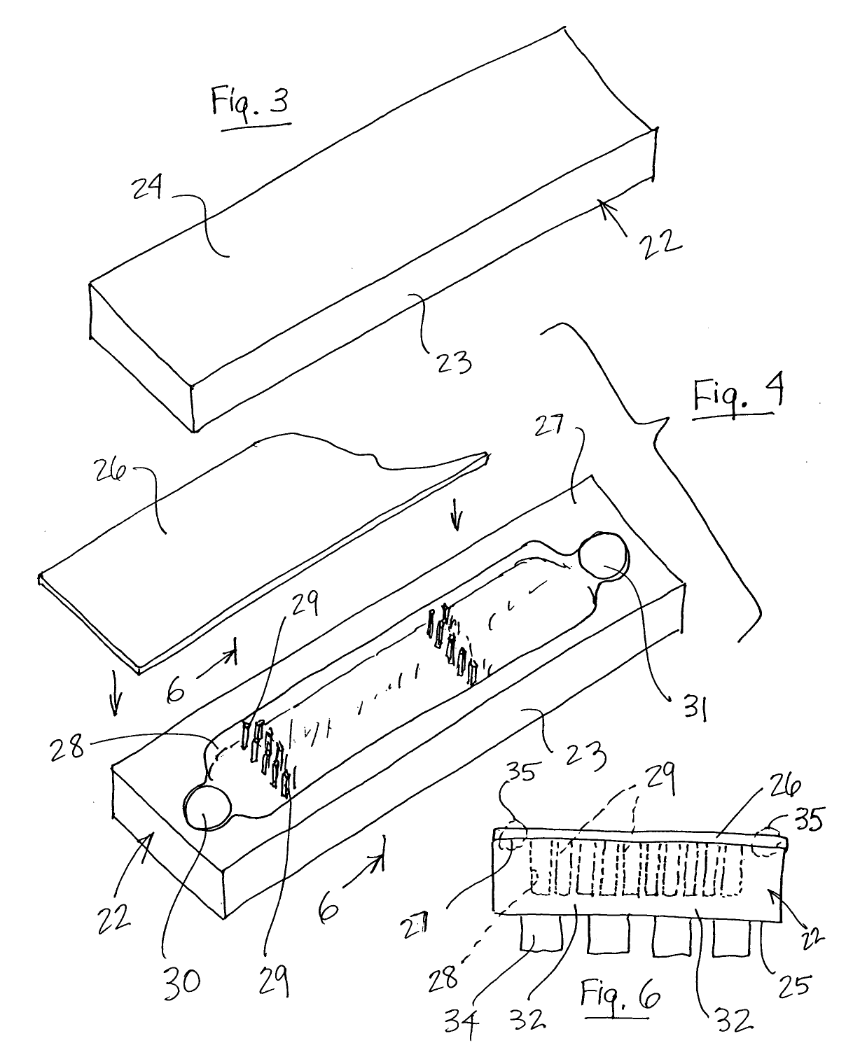

Reference is next made to FIGS. 3, 4, 5 and 6 showing one embodiment of a cold plate configuration in accordance with the present invention.

FIG. 3 shows a first plate component in the form of a base block 22 for the cold plate prior to any machining, while FIGS. 4, 5 and 6 show various views of the cold plate after machining and assembly. As shown in FIG. 1, the unmachined base block 22 has a generally rectangular configuration with a first surface 24 to be machined and an opposite second surface 25 (FIG. 3) to which a plurality of electronic chips or other components will be connected when machining and assembly is completed. A peripheral edge 23 extends between the surfaces 24 and 25. The base block 22 may be constructed of any material which is heat conductive and will function in the construction of a cold plate. More preferably, the material should be one which is not only heat conductive, but one which can be subject to connection via friction stir welding as well. The most preferable of this are aluminum and copper and alloys thereof. However, any of the materials mentioned above as being capable of friction stir welding may also be considered.

To provide the cooling capability of this embodiment, a cavity 28 and a plurality of pin or peg-shaped fins 29 are machined into the base plate 22 from the surface 24. By doing so, each of the fins 29 includes a first end integrally formed with block 22 at the base or bottom of the cavity 28 and a second, free end spaced from the cavity base. An inlet 30 and an outlet 31 are also machined into the base plate 22 at each end of the cavity 28. During operation, cooling fluid such as a mixture of glycol and water is introduced into the cavity 28 through the inlet opening 30 and exits from the cavity 28 through the outlet opening 31.

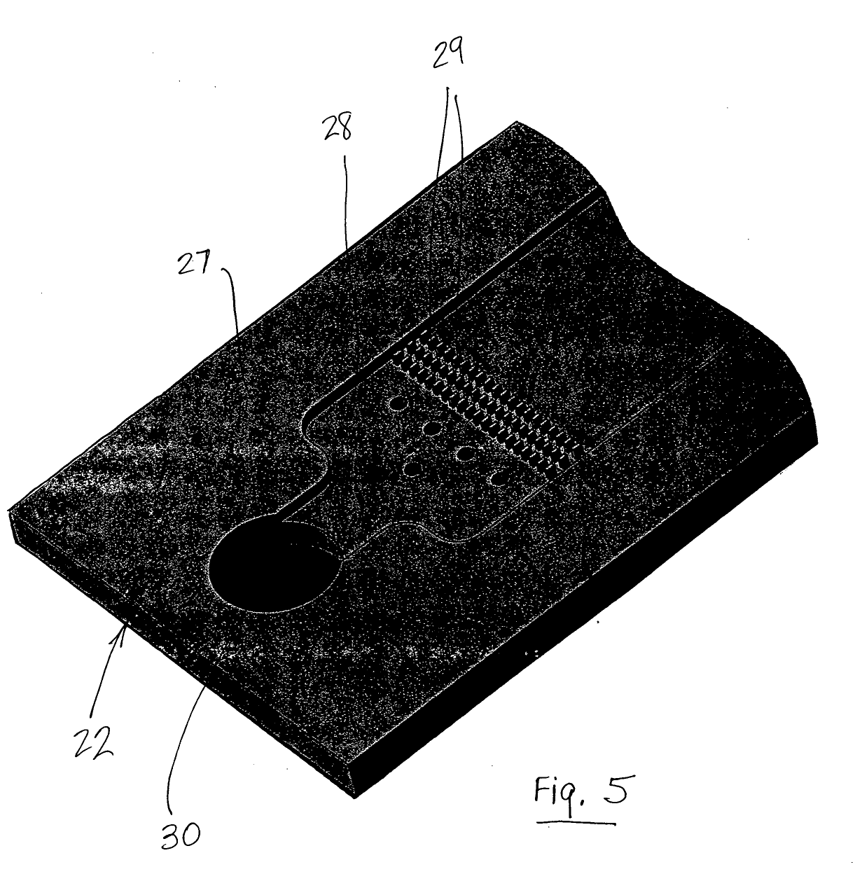

As shown in FIGS. 4, 5 and 6, the cavity 28 extends between the inlet and outlet openings 30 and 31 and has a configuration which is spaced inwardly from the outer side edges 23 to define the cover receiving surface portion 27 shown in FIGS. 4 and 5. This surface portion 24 surrounds the entirety of the cavity 28. The pin or peg-shaped fins 29 are formed and distributed throughout a substantial portion of the cavity 28. Like the cavity 28, the fins 29 are machined into the block 22 from the surface 24. Accordingly, the first ends, sometimes also called the proximal or base ends, of the fins 29 are integrally formed with the portion 32 of the base between the bottom of the cavity 28 and the cooling surface 25.

Preferably, the second ends, sometimes also called the outer or distal ends, of the fins 29 are machined to lie in a common plane. In the preferred embodiment of FIGS. 4, 5 and 6, this plane is also common with the plane of the surface portion 27 surrounding the cavity 28. A variety of known machining and/or milling processes may be used for forming the cavity 28 and the plurality of fins 29 within such cavity. As used herein, the term “machining” shall include machining, milling or any other process of removing material from a stock item or forming such item into a milled or machined product.

After the cavity 28, the fins 29 and the inlet and outlet openings 30 and 31 are machined into the base block 22, a cover plate or member 26 is positioned into engagement with the cover receiving surface portion 27. If no material is machined from the surface 24, the surface portion 27 will be the portion of the surface 24 surrounding the cavity 28. The cover plate 26 is then connected to this surface portion 27. While various connection techniques can be utilized to connect the cover plate 26 to the surface 27, a preferred process in accordance with the present invention is friction stir welding (FSW) as described above.

In the embodiment of FIGS. 3-6, the lap joint between the bottom or base engaging surface portion of the cover plate 26 and the surface portion 27, are friction stir welded as shown in the area of reference character 35 in FIG. 6. This friction stir welding technique provides a hermetic seal between the cover plate 26 and the surface portion 27 to seal the interior of the cavity 28. When the cover plate 26 is connected as shown in FIGS. 4 and 6, the outer or distal ends of the fins 29 are in substantial engagement with the inner surface of the connected plate 26.

A plurality of chips or other electronic components 34 may be connected to the cooling surface 25 of the base 22 to cool such components 34 during operation. If desired, chips or other electronic components may also be connected to the outer surface of the cover plate 26.

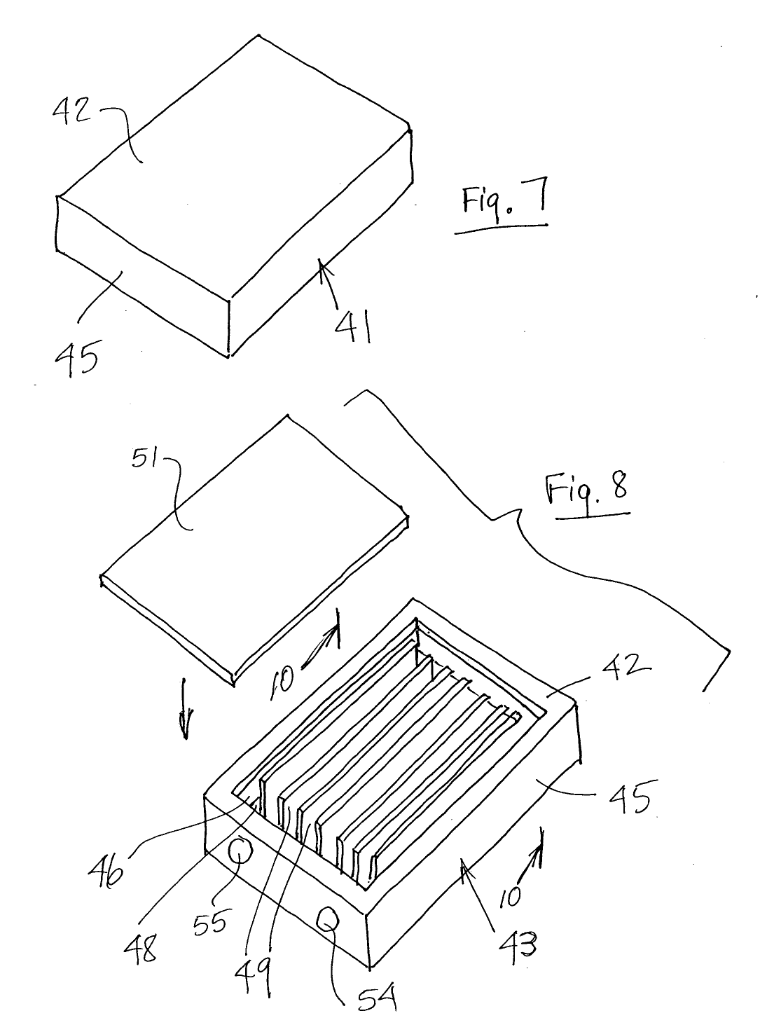

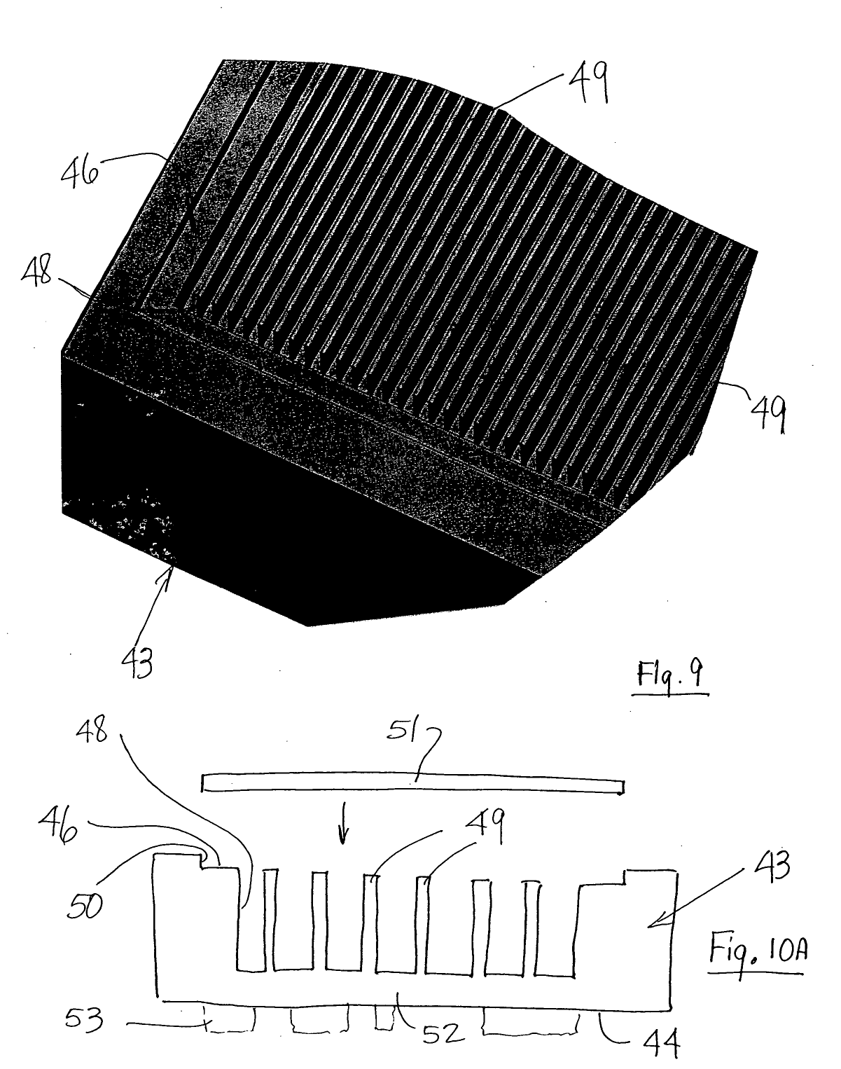

A further embodiment in accordance with the present invention is the cold plate embodiment illustrated in FIGS. 7, 8, 9 and 10. FIG. 7 shows a base block 41 from which the first plate member in the form of the base member 43 (FIGS. 8, 9 and 10) is machined. As shown, the base block 41 is a generally rectangular block having a machining surface 42, an opposite component mounting or cooling surface 44 (FIG. 10) and a peripheral edge 45. As with the base block 22 of FIG. 3, the base block 41 of FIG. 7 may be constructed of any material which is heat conductive and will function in the construction of a cold plate. Preferably, the material should also be one which can be subject to connection via friction stir welding such as, but not limited to, aluminum, magnesium, copper, steels, titanium, nickel and alloys thereof.

The machined block of FIGS. 8, 9 and 10 includes a cover receiving recess, a fin containing cavity 48 and a plurality of elongated fins 49 within the cavity 48. Each of these elements is machined into the base block 41 from the surface 42. The plate receiving recess includes a cover receiving surface portion 46 and is machined to a depth shown by the reference character 50 and of a configuration which is designed to receive the cover plate 51.

The cavity 48 is similarly machined into the base block 41 from the surface 42 and includes the plurality of fins 49. In this embodiment, the fins 49 are longitudinally extending fins which have a first or proximal end integrally formed with the portion 52 of the base member 43 between the bottom of the cavity 48 and the cooling surface 44 of the base 43. These fins 49 are closely adjacent to one another, are parallel to one another and form cooling fluid channels between them substantially throughout their entire length. The second or distal edges of the fins 49 preferably lie in a common plane which is also coplanar with the cover receiving surface portion 46 of the cover receiving recess. Thus, when the cover member 51 is positioned into the receiving recess of the base 43 as shown in FIGS. 10A and 10B, the inner surface of the cover member 51 is in substantial engagement with the top edges of the fins 49. After positioning of the cover 51 in this position, the cover 51 is connected to the base 41 via friction stir welding. FIG. 10B shows the connection via friction stir welding in the area 57. Specifically, in this embodiment, the friction stir welding is along the seam between the edges of the cover 51 and the edge 50 defining the depth of the cover receiving recess.

Inlet and outlet ports 54 and 55 are provided at the ends of the base 43 to provide cooling fluid into and to remove cooling fluid from the interior of the cavity 48 and the flow channels between the fins 49. These ports 54 and 55 are connected with a manifold pocket to distribute the cooling fluid into the channels between the fins 49.

As shown in FIGS. 10A and 10B, a plurality of chips or other electronic components 53 may be mounted to the cooling surface 44 to remove heat from such components during operation. If desired, chips or electronic components may also be mounted to the outer surface of the cover 51.

It should be noted that in the embodiment of FIGS. 3-6, the fins are pin or peg-shaped structures having a first end integrally formed with the base via machining, while in the embodiment of FIGS. 7-10, the fins are elongated, narrow structures or ribs having a first edge integrally formed with the base via machining. Fins may also be machined from the base in the form of baffles or the like to direct flow of cooling fluid from the inlet to the outlet. The formation of fins in a base, whether in the form of pegs, elongated ribs or baffles, and whether or not formed by machining, define fluid flow channels for directing cooling fluid from a fluid inlet to a fluid outlet. Accordingly, unless otherwise defined, the term “fin” as used herein shall include any structure positioned between first and second plate members of a cold plate which define fluid flow channels, or direct fluid from a fluid inlet to a fluid outlet.

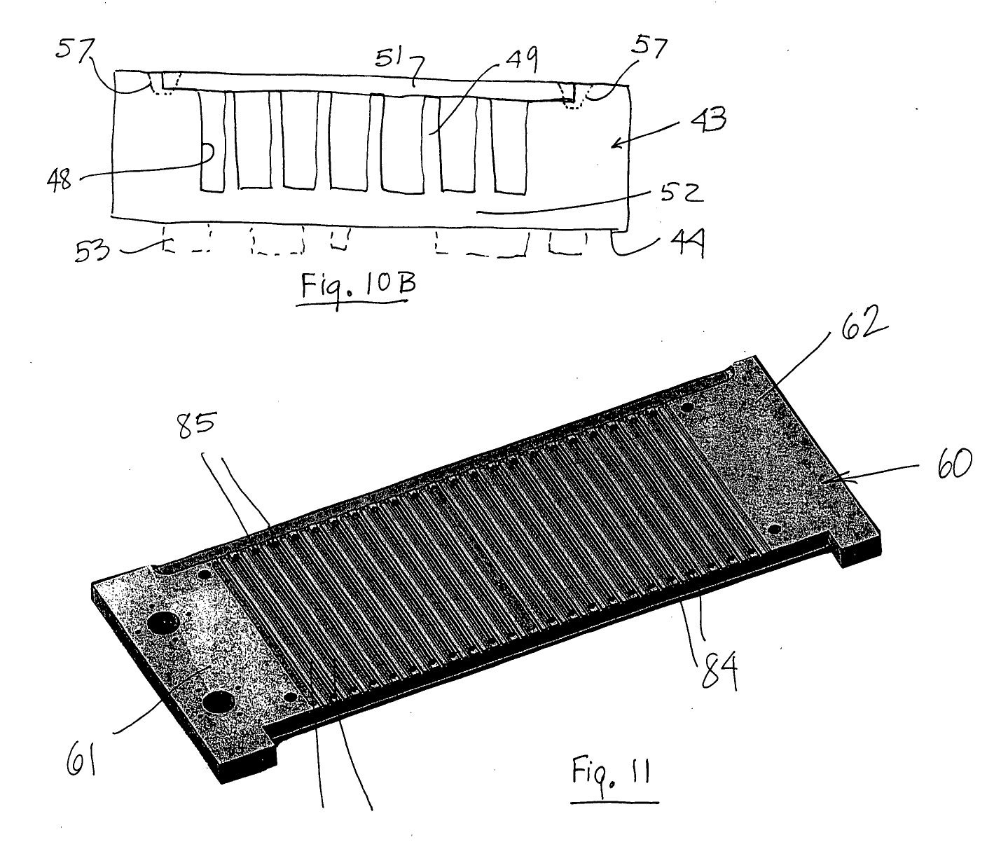

A further embodiment of a cold plate design is illustrated generally in FIG. 11 and more specifically, in FIGS. 12-16. The cold plate embodiment 60 as shown in FIG. 11 is a cold plate design for providing cooling capability to circuit boards containing electronic components. In general, the cold plate 60 includes a pair of end sections 61 and 62 and a plurality of cooling ribs 64 machined into the base cold plate member 60.

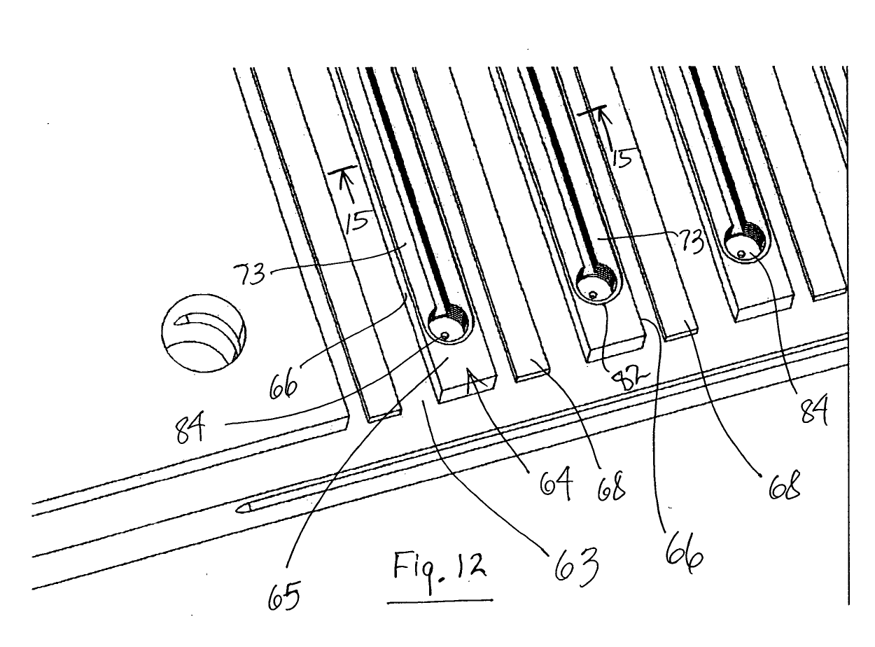

As with the other embodiments described above, the cold plate configuration 60 and its various cooling fins, etc. are machined from an unmachined base block. As shown in FIGS. 12 and 13, the plurality of cooling ribs 64 are machined into at least one surface of the cold plate 60. Each of the cooling ribs 64 is integrally formed with the base 63 and extends outwardly therefrom. Each of the ribs 64 includes an outermost surface 65 and a pair of cooling sides 66,66. The plurality of cooling ribs 64 are generally parallel to one another and are laterally spaced along a substantial portion of the cold plate configuration 60. An electronic component mounting rib 68 is positioned midway between each of the cooling ribs 64.

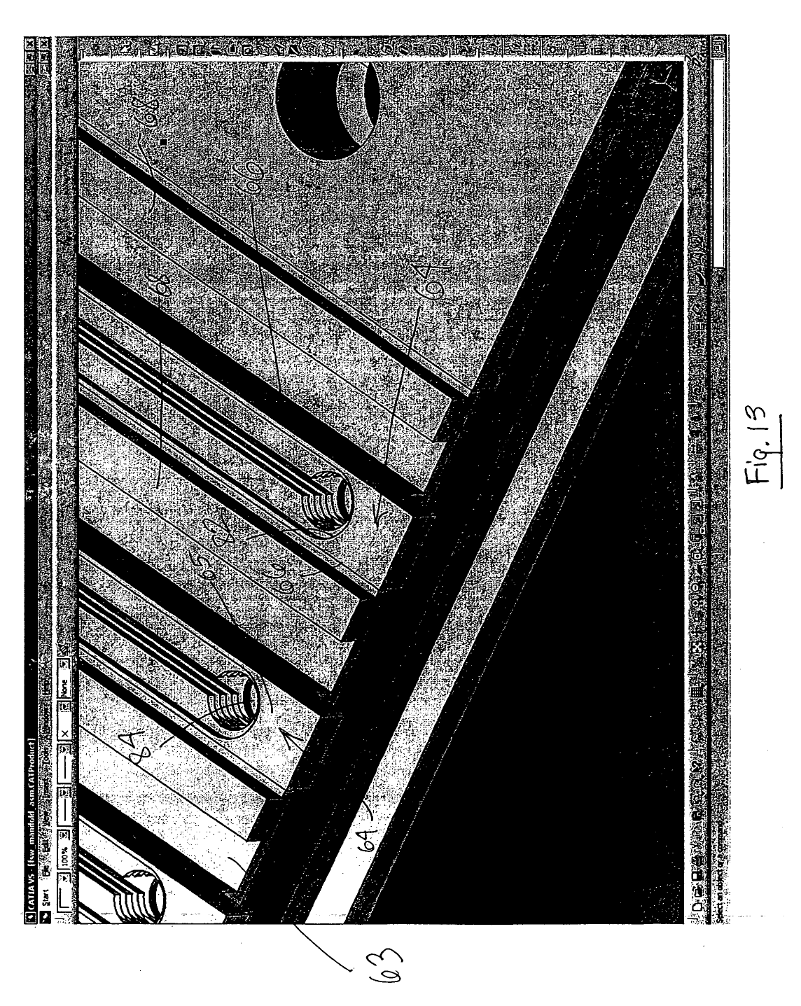

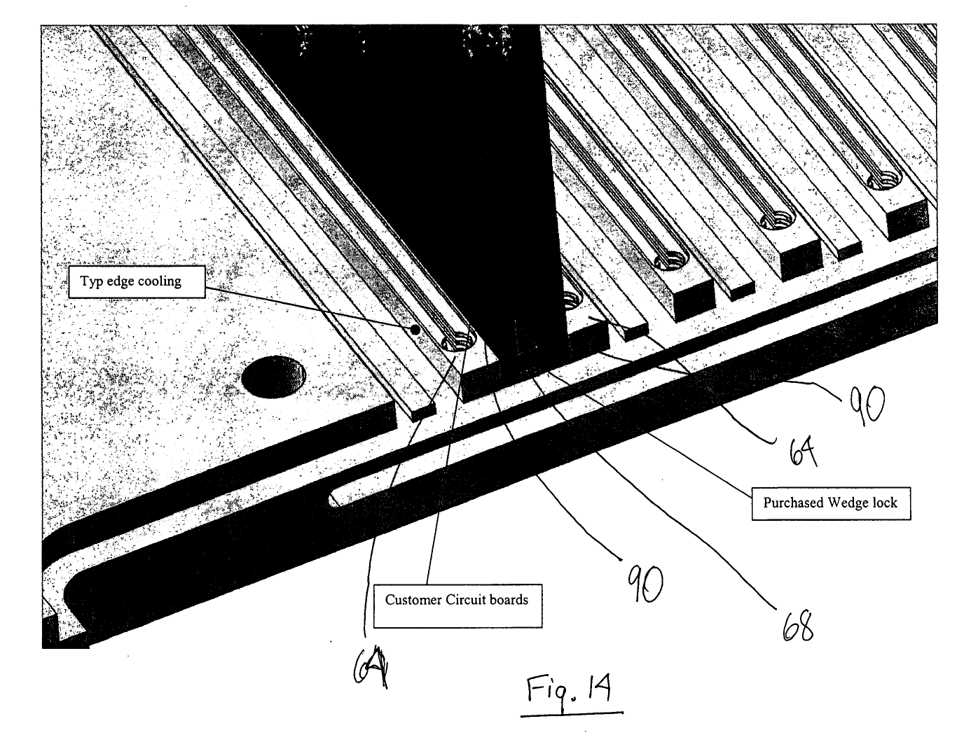

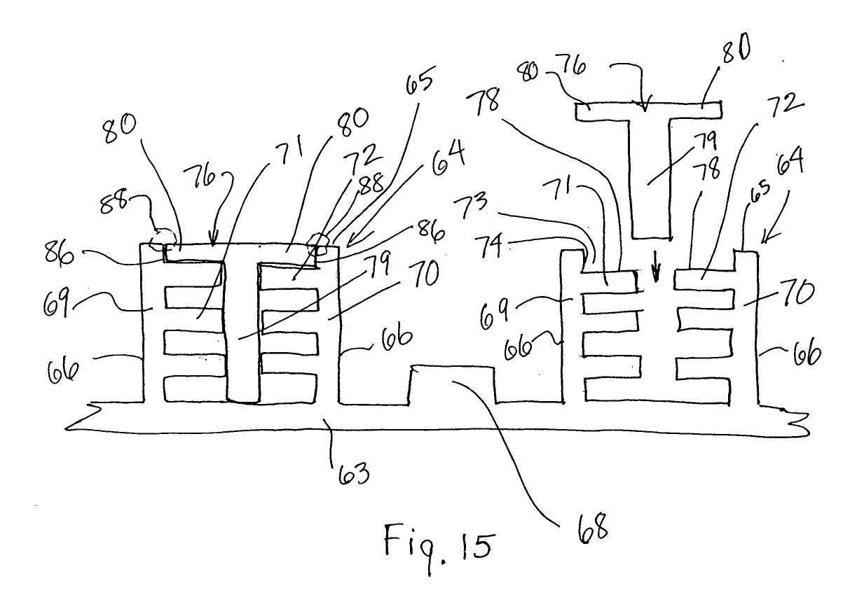

As shown best in FIG. 15, and more generally in FIGS. 12 and 13, each of the cooling ribs 64 includes opposite cooling walls 69 and 70. The outer surfaces of these walls 69 and 70 form the cooling sides 66. Each of the cooling walls 69 and 70 includes a plurality of inwardly facing longitudinal fins 71 and 72, respectively. Each of these fins 71 and 72 extends inwardly from their respective cooling walls 69 and 70 toward one another, with their innermost edges substantially aligned and equally laterally spaced from one another. In accordance with the present invention, these fins 71 and 72 are formed by machining, and more specifically, in accordance with the preferred embodiment, by a “T” slot cutter.

A cover plate receiving recess 73 is machined within the outer surface 65 of each of the ribs 64 to receive a T-shaped plug or cover member 76 (shown only in FIGS. 15 and 16). This recess includes the inner edge surface 74 (and the outermost surface 78) of the outermost of the fins 71 and 72 as shown best in FIG. 15. The T-shaped plug or cover member 76 is an elongated member having a “T”-shaped cross section with a base leg 79 and a pair of laterally extending arms 80,80 at the top of the leg 79. As shown, the T-shaped cover 76 is designed to be inserted into the area between the innermost ends of the fins 71 and 72, with the outer arms 80,80 seated within the cover receiving recess 73 in the top surface 65. This is shown best on the right-hand side of FIG. 15. Accordingly, to permit insertion of the base leg portion 79 between the ends of the fins 71 and 72, the width dimension of the base portion 79 must be no greater than, and is preferably slightly less than the distance between the innermost ends of the fins 71 and 72. This permits the base portion to be inserted between them. Similarly, the height of the base portion 79 (the distance between its distal end and the bottom surface of the arms 80) should be no greater than, and preferably slightly less than, the distance between the outermost surface 78 and the inner base surface between the fins 71 and 72. The arms 80,80 of the T-shaped cover 76 are machined so that they fit within the recess 73 in each of the cooling channels 64.

As shown best in FIGS. 12 and 13, each end of the recessed portions 73 is curved as shown by reference character 82. Each end of the cooling channel includes a cooling fluid inlet port 84 (FIG. 12), with the opposite end including a cooling fluid outlet port 85.

In the preferred embodiment, the mounting ribs 68 and the cooling ribs 64, including the cooling walls 69 and 70 and the plurality of fins 71 and 72 are machined from a single piece of base stock. Thus, the mounting ribs 68 and the entirety of the cooling ribs 64 are integral with one another.

After machining is complete, assembly includes inserting the T-shaped cover member 76 into the cooling channel 64 so that the base portion 79 extends between the innermost edges of the fins 71 and 72 and the arms 80,80 seat within the recessed area 73. The T-shaped cover 76 is then connected to the cooling channels 64 as shown in the left-hand side of FIG. 15. In accordance with the present invention, this connection is preferably made by friction stir welding applied at the joint or seam 86 in the area indicated by reference character 88 between the edges of the arms 80,80 and the edges of the recess 73.

FIG. 14 shows the embodiment of FIGS. 11-13, 15 and 15 used to cool components on a circuit board via edge cooling. Specifically, as shown in FIG. 14, a pair of circuit boards 90,90 are positioned between a pair of cooling ribs 64,64 and substantially in engagement with the cooling sides 66,66 and retained in that position by the rib or wedge lock 68.

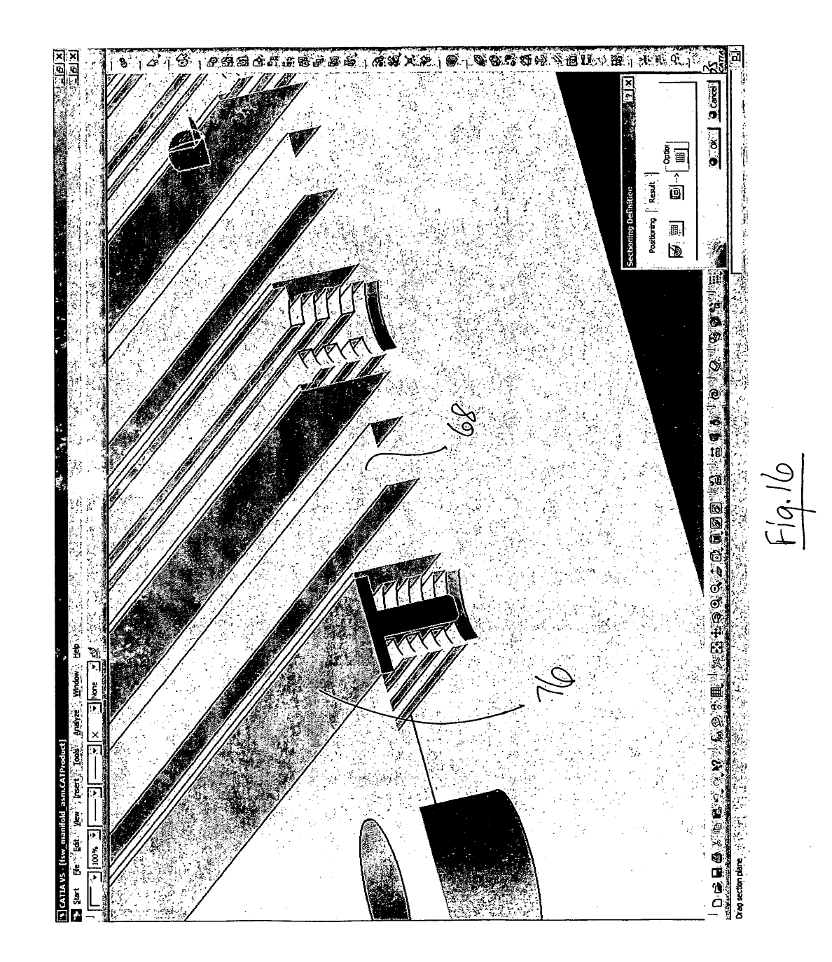

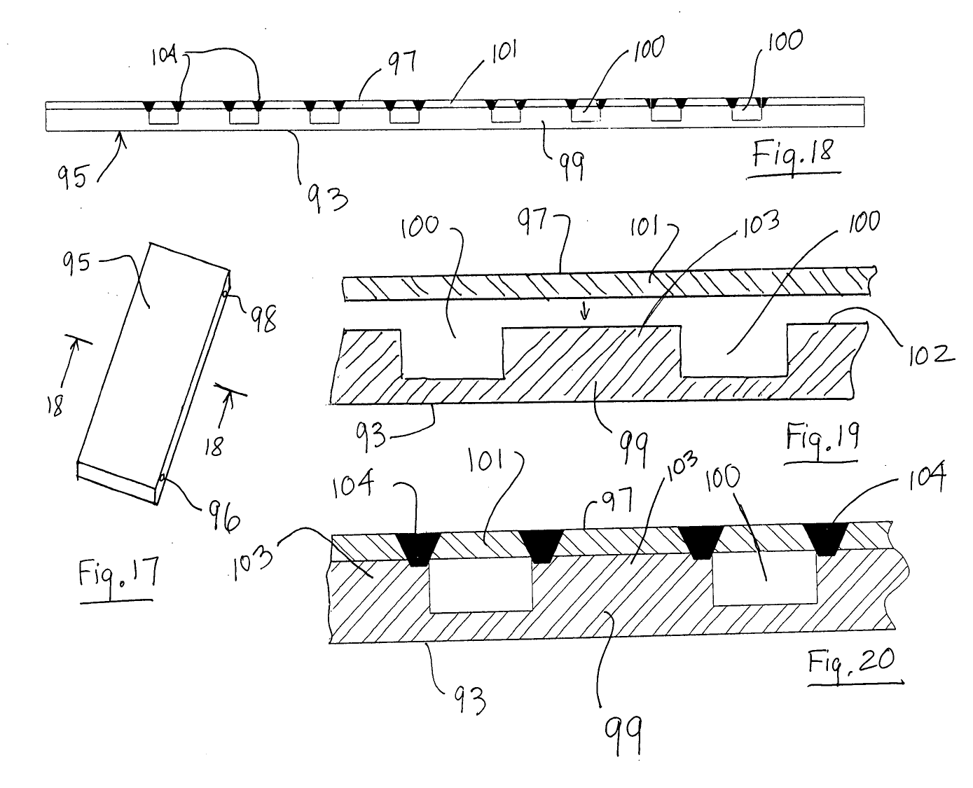

FIGS. 17-38 show various embodiments of cold plate configurations comprising a first plate member in the form of a base, a second plate member in the form of a cover, and one or more fin structures or flow channels formed in the base, or in the cover, or both, by machining or the like, with the base and the cover connected in a hermetically sealed relationship via friction stir welding. In some embodiments, the outer edges of the fins in one of the plate members are in substantial engagement with the inner surface of the other plate member, while in other embodiments, portions of such inner surface adjacent to the outer edges of the fins are connected to those fins via friction stir welding. In all of these embodiments, the first and second plate members are constructed of materials that are heat conductive and that can be friction stir welded.

The embodiments of FIGS. 17-20 show a cold plate 95 which is generally elongated and may have a thickness dimension of up to ½ inch or more, a width dimension of up to 15 inches or more and a length of any dimension up to 20 feet or more. The cold plate is constructed of one or more heat conductive metals which, preferably, can also be friction stir welded. Such metals include aluminum, copper, magnesium, titanium, various steels, nickel and the alloys thereof, with the most preferable being aluminum and copper and their alloys. Positioned at opposite ends of the cold plate 95 is a cooling fluid inlet 96 and a cooling fluid outlet 98. The cold plate also includes opposite, substantially planar cooling surfaces 93 and 97 to which chips or other electronic components may be connected.

FIGS. 18, 19 and 20 show various cross-sectional views of the cold plate 95. Specifically, this cold plate configuration includes a base member 99, a plurality of elongated fluid flow channels 100 machined into the base 99 and a cover or cover member 101. As shown best in FIG. 19, the base 99 includes a machining surface from which the channels 100 are machined and which ultimately forms the cover receiving surface for the cover 101. Each of the channels 100 can also be considered as being defined by the ribs or fins 103 between adjacent channels 100. The cold plate of FIGS. 18-20 is made by providing an unmachined base stock (not shown). From this base stock, the plurality of elongated channels 100 are machined. Following this machining, a cover member 101 is provided and positioned so that the inner surface of the cover 101 engages the outer or cover receiving surface portion 102 of the base. The cover 101 is then connected with the base 99 via friction stir welding in the areas 104 as indicated. Specifically, the cover 101 is connected with the base via friction stir welding in areas along the sides of each channel 100, and thus also on the sides of each rib or fin 103. In this way, the flow channels 100 are isolated from one another. The friction stir welding in this embodiment is a lap connection in which the friction stir welding tool extends through the entire width of the cover 101 and partially into the base at the outer edges of the fins 103. Chips or other electronic components may be mounted to either or both of the cooling surfaces 93 and 97.

Suitable manifolds at each end of the cold plate 95 connect the inlet 96 and the outlet 98 to the cooling fluid channels 100.

The cold plate configuration 105 of FIGS. 21-24 is similar to that of the cold plate 95 of FIGS. 17-20 in that the cold plate 105 is a generally thin, elongated structure with a thickness of up to ½ inch or more and has a pair of substantially planar cooling surfaces 107 and 113 for the mounting of chips or other electronic components to be cooled. The cold plate 105 may be up to 12 inches or more in width and up to 12 feet or more in length. The cold plate 105 includes an inlet 106 and an outlet 108 at its opposite ends and suitable manifolds at each end to connect the inlet 106 and the outlet 108 via a plurality of flow channels.

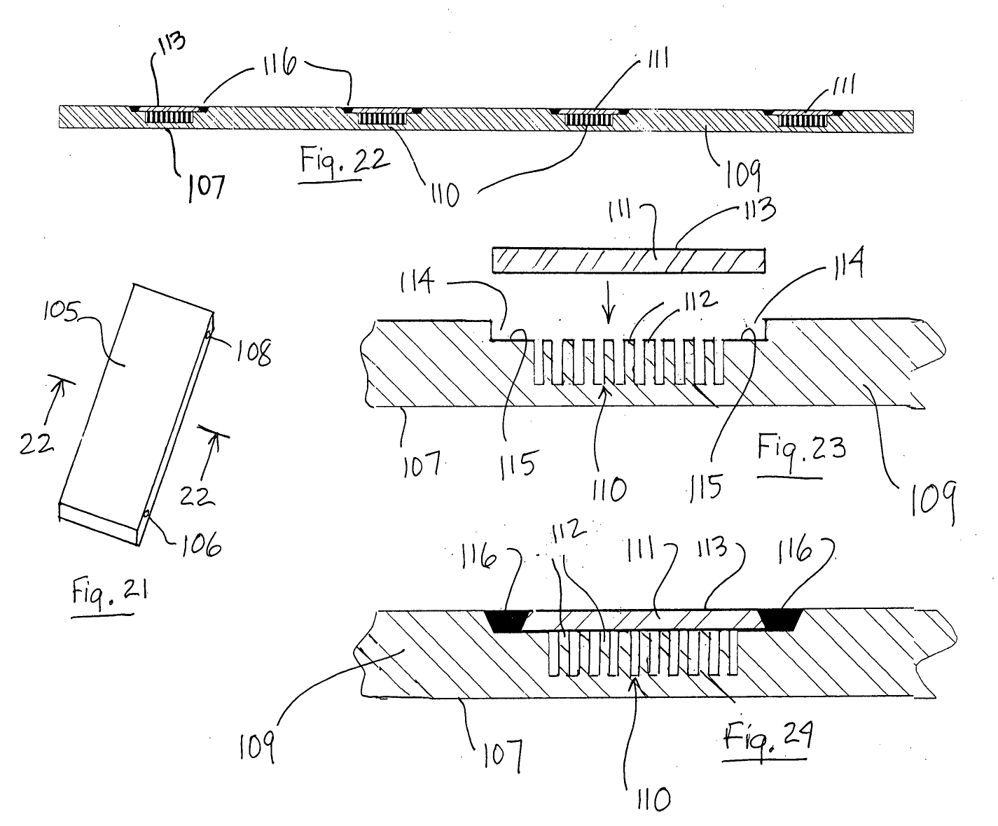

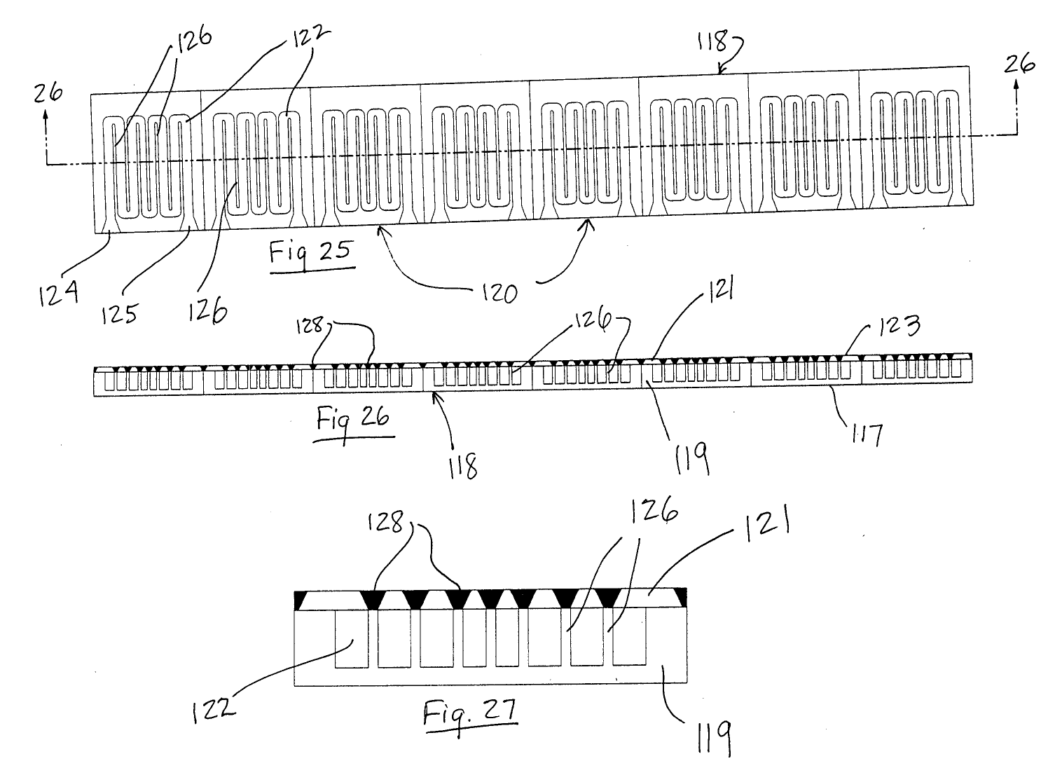

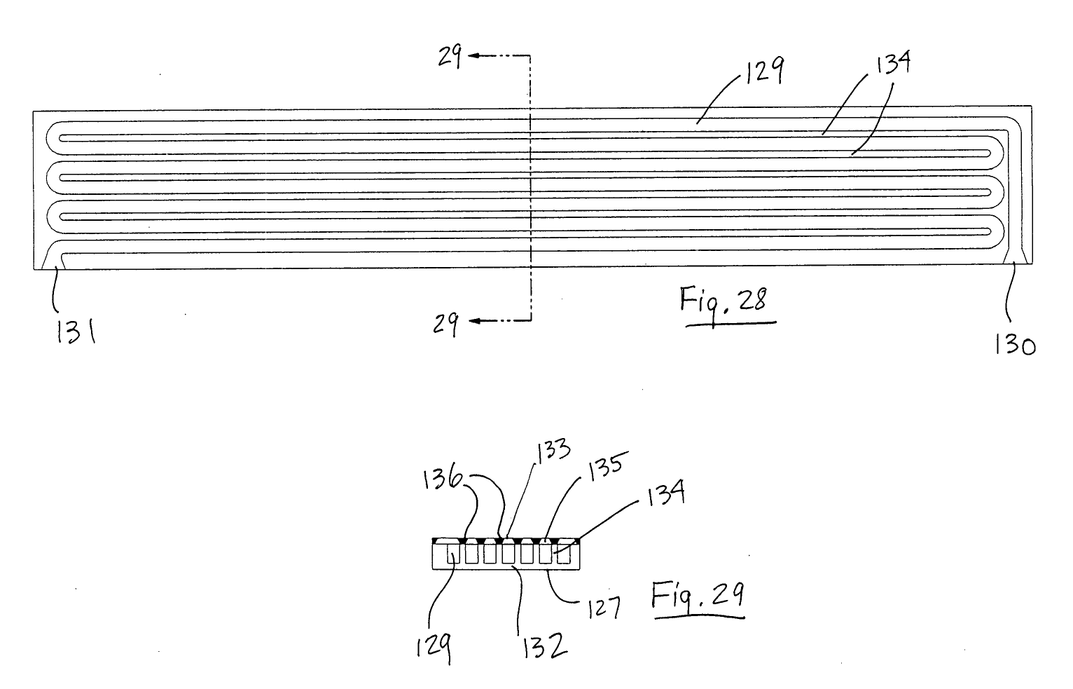

FIGS. 22, 23 and 24 show various cross-sectional configurations of the cold plate 105. Specifically, the cold plate 105 includes a base 109, a plurality of cooling channels 110 and a cover or cover plate 111 associated with each of the cooling channels 110. As shown best in FIGS. 23 and 24, each of the cooling channels 110 includes a series of fins 112 (shown in FIG. 22 as solid lines) integrally machined from the base 109. Each of the fins 112 includes a first end which is integrally formed with the base 109 and a second, free end spaced outwardly from the first end. As shown, the second, outer ends of the fins 112 lie substantially in a common plane. Each of the cooling channels 110 is also provided with a cover receiving recess 114 on opposite sides of the cooling channel 110. These recesses 114 include a cover receiving surface portion 115 to receive a corresponding cover 111. The various covers 111 are connected to the base 109 within the recesses 114 via friction stir welding.

Accordingly, the method of making the cold plate configuration of FIGS. 21-24 includes providing an unmachined piece of base stock (not shown) and machining into that base stock from a machining surface side, the plurality of fins 112 and the recesses 114. During this machining process, the outer ends of the fins 112 are machined to lie in a common plane together with the cover receiving surfaces 115. A cover 111 is then positioned within the cover receiving recesses 114 and the cover 111 is connected with the base 109 via friction stir welding in the areas 116. In this embodiment, the friction stir welding occurs along a seam or butt joint between the side edges of the cover 111 and the side inner edges of the recesses 114. Chips or other electronic components may be mounted to either or both of the cooling surfaces 107 and 113.

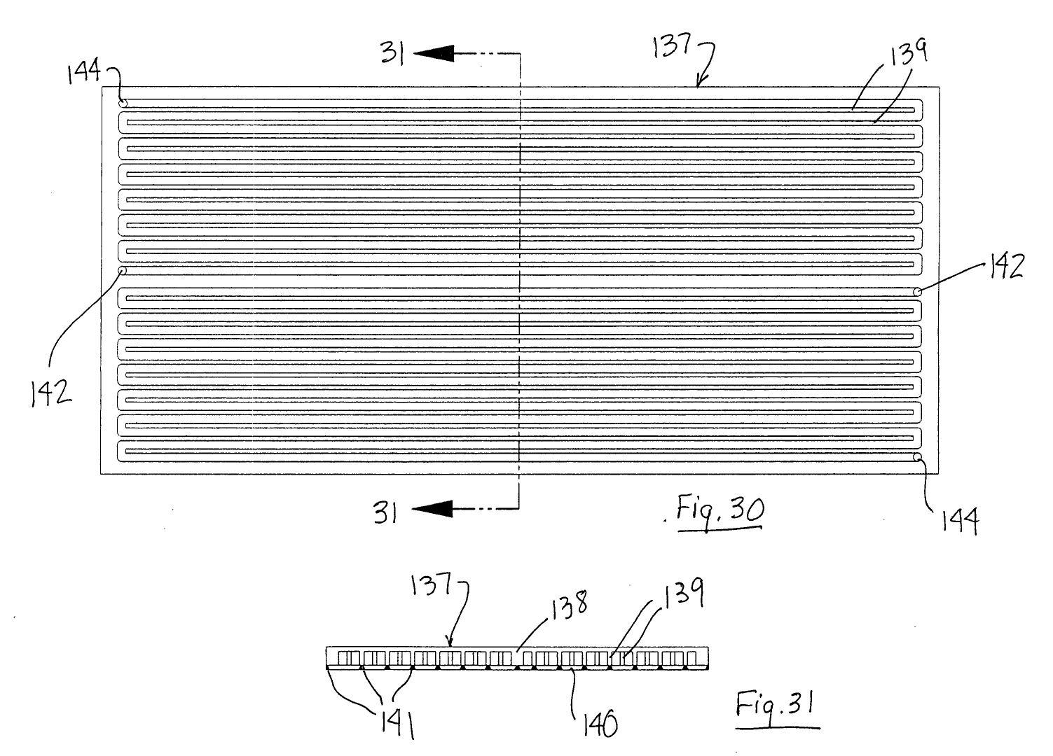

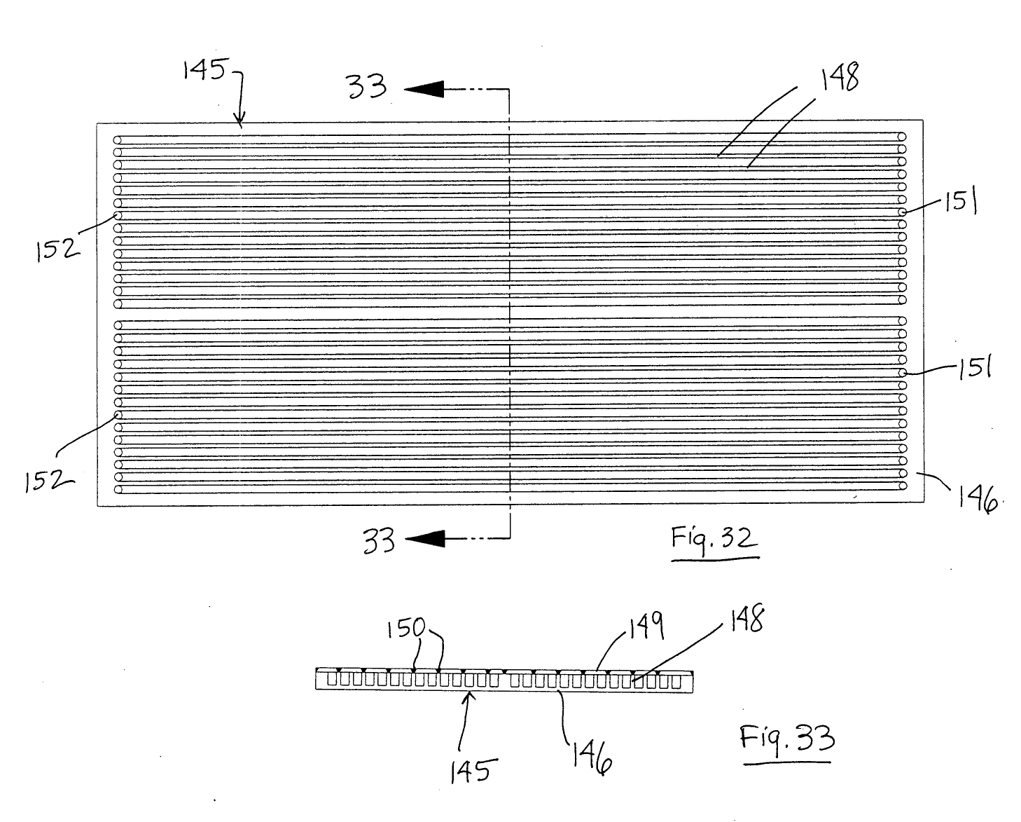

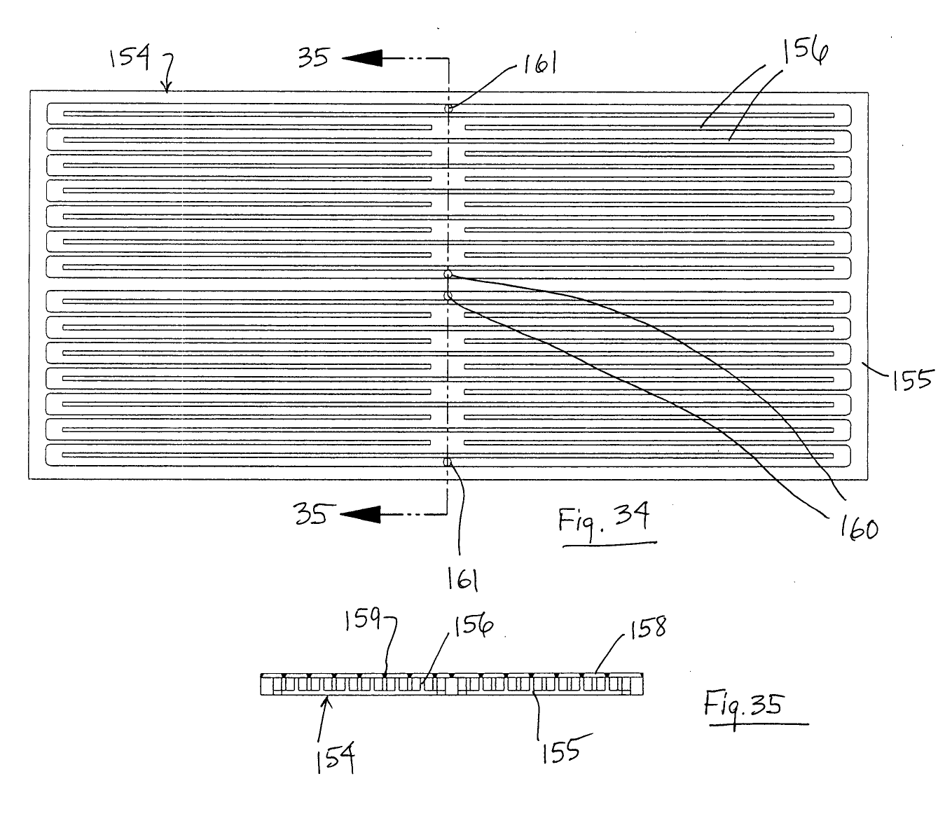

The cold plate 118 of FIGS. 25-27 is an elongated, relatively thin structure having opposite, substantially planar cooling surfaces 117 and 123 to which chips or other electronic components may be mounted or placed for cooling.

Specifically, the cold plate 118 includes a base 119, a plurality of cold plate segments 120 machined from the base 119 and a cover or cover plate 121. As shown best in FIG. 25, each of the cold plate segments 120 includes a cooling fluid channel 122 with an inlet 124 and an outlet 125. The cooling fluid channel 122 in each of the cold plate segments 120 is formed and defined by a plurality of fins 126 which are machined from the base 119. Thus, as shown best in FIG. 27, each of the fins 126 has a first end integrally formed with a base and a second end spaced outwardly from the first end so that the outer ends of the fins 126 lie substantially in a common plane and in a plane common with the machining surface of the base 119. A single cover or cover plate 121 covers all segments 120 and is joined with the base 119 via friction stir welding in the areas 128. As shown, in this embodiment, not only is the cover 121 connected with the base 119 between each adjacent pair of cold plate segments 120, but is also connected via friction stir welding with the top edges of each of the fins 126. By connecting the cover to the top edges of the fins 126 via friction stir welding, the heat transfer between the outer surface 123 of the cover 121 and the cooling fluid is maximized. This provides a cold plate structure which is particularly applicable for chips or other electronic components to be mounted to both the outer cooling surface side 117 of the base 119 as well as the outer cooling surface 123 of the cover 121.

The cold plate of FIGS. 28 and 29 is similar to that of FIGS. 25-27, except that a single flow channel 129 is formed between the inlet 130 and the outlet 131. Specifically, the cold plate of this embodiment includes a base 132 and a plurality of elongated fins 134 machined into the base 132 to form the flow channel 129. A cover 135 is connected with the base 132 and the top edges of each fin 134 via friction stir welding. Specifically, the friction stir welding occurs in the areas designated by the reference character 136. Chips or other electronic components may be connected with either or both of the cooling surfaces 127 and 133 of the base and cover, respectively.

FIGS. 30-35 show various further embodiments of cold plate configurations in accordance with the present invention. In each, the cold plate is a relatively thin structure having a thickness of up to ½ inch or more, a width of up to 12 inches or more and a length of up to 20 feet or more. Each such cold plate structure comprises a pair of substantially planar cooling surfaces, one formed by the outer surface of the base member and the other formed by the outer surface of the cover. Each of these embodiments also includes a plurality of fluid directing fins machined from the base and a cover secured to the base and, where appropriate, to the outer surfaces of each of the fins via friction stir welding to define one or more fluid flow channels.

More specifically, the embodiment of FIGS. 30 and 31 is a back-and-forth flow/twin cooling cold plate with a base 138, a plurality of elongated fluid directing fins 139 machined from the base 138 and a cover 140 connected with the base 138 and to the outer ends of alternate fins 139 via friction stir welding. Specifically, the friction stir welding occurs in the areas designated by the reference character 141. Inlets 142,142 and outlets 144,144 are provided at each end of the cold plate.

The embodiment of FIGS. 32 and 33 is a straight flow/twin cooling cold plate 145. This structure includes a base 146, a series of fluid directing fins 148 machined from and thus integrally formed with the base 146 and a cover 149. The fins 148 define one or more fluid flow channels. As shown in FIG. 33, the cover 149 is connected to the base 146 and to the outer ends of alternating fins 148 via friction stir welding in the areas 150. As shown in FIG. 32, opposite ends of the cold plate 145 are provided with a series of cooling fluid inlets 151 and cooling fluid outlets 152.

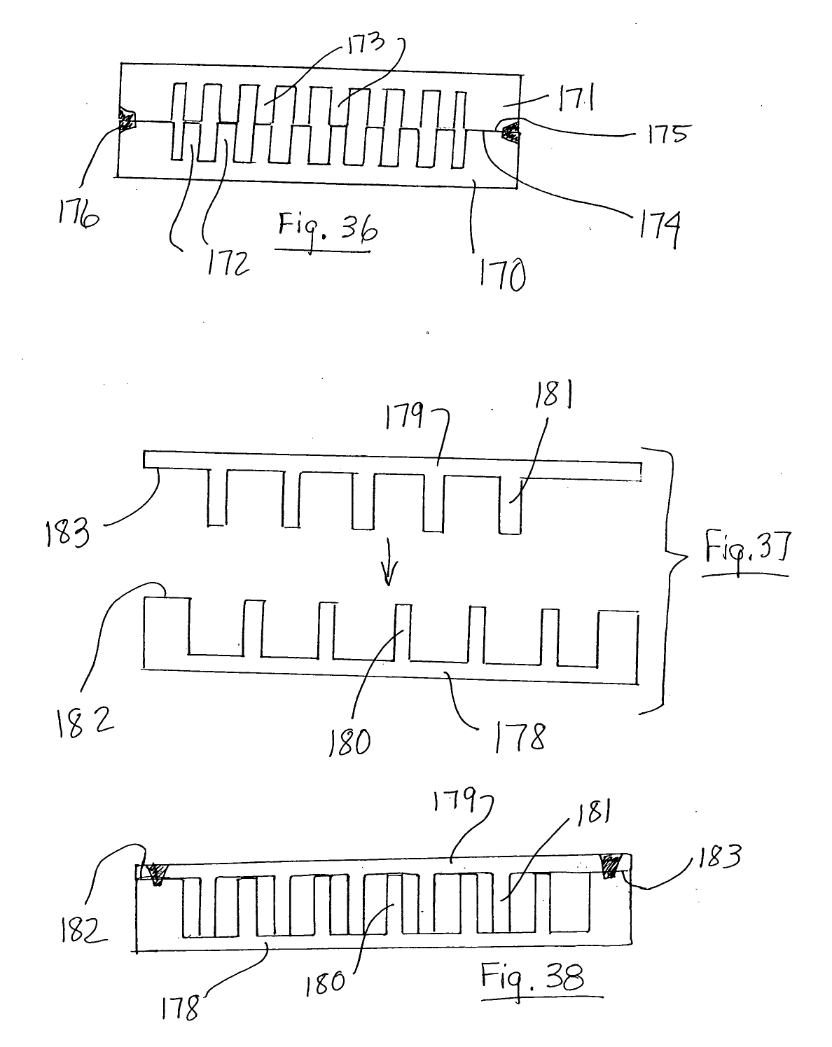

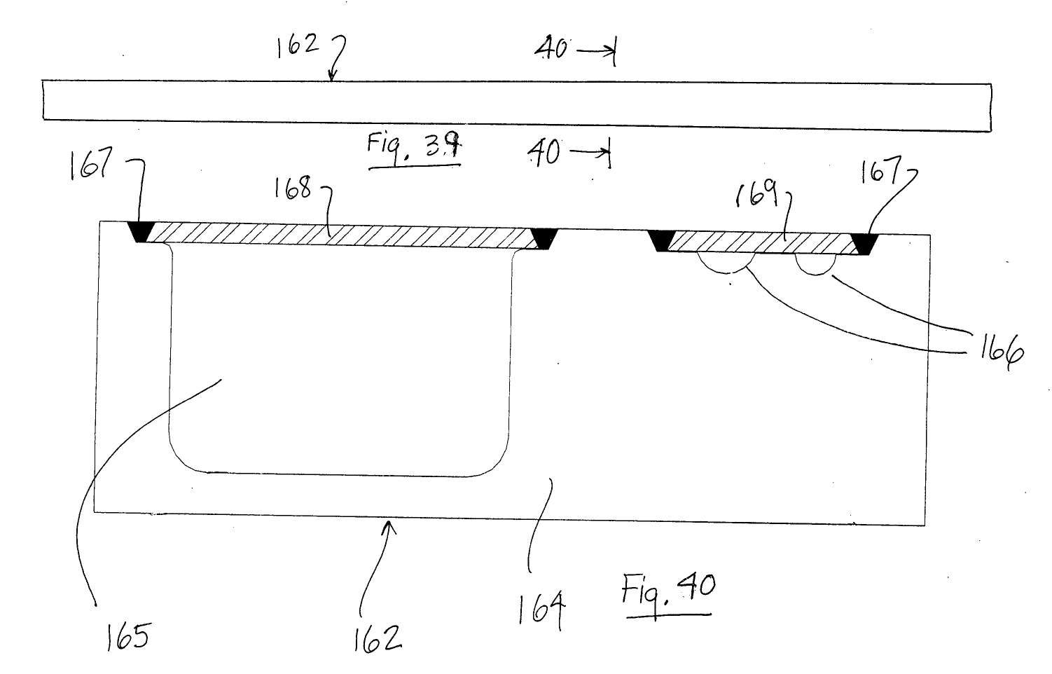

The embodiment of FIGS. 34 and 35 is a center flow/twin cooling cold plate 154. This structure also includes a base 155, a series of flow directing fins 156 defining one or more flow channels and a cover 159. The fins 156 are machined from, and thus integrally formed with, the base 155. The cover 158 is connected with the base 155 and with alternate fins 156 via friction stir welding in the areas 159. The cooling fluid circuit of the cold plate 154 includes a pair of cooling fluid inlets 160 and a pair of cooling fluid outlets 161.

All of the various cold plate embodiments described and discussed above include a first or base member, a second or cover member and a series of fins or other fluid directing projections or channels machined into one or both of such members. Such embodiments also include the first and second members connected with each other in a hermetically sealed relationship via friction stir welding. In some embodiments, the friction stir welding merely extends between the members in the area surrounding the series of fins or channels, while in other embodiments, the members are connected with the outer ends of the fins via friction stir welding as well. These latter embodiments are particularly applicable for the mounting of chips or other components on the outer cooling surfaces of both members.

FIGS. 36-38 show further embodiments of cold plate configurations in accordance with the present invention. In each of the above-described embodiments, all of the fins or flow channels are machined into the base or base plate portion of the cold plate, with the cover being a relatively flat, planar structure on both sides. It is contemplated, however, that both the first or base plate member as well as the second or cover plate member of a cold plate in accordance with the present invention could be provided with integrally machined fins or cooling channels.

Specifically, FIG. 36 shows a cold plate configuration in accordance with the present invention having a base plate 170 and a cover plate 171. Both the base plate 170 and the cover plate 171 include a plurality of fins 172 and 173, respectively. Each of the base 170 and cover 171 plates also include a corresponding edge surface 174 and 175. When assembled, these edge surfaces 174 and 175 mate with one another to enclose the fins 172, 173 and the fins 172, 173 mate with one another to define flow channels between them. In the embodiment of FIG. 36, the base plate 170 and the cover plate 171 are connected together via friction stir welding in the area designated by the reference numeral 176. This is a butt weld along the seam formed by the surfaces 174 and 175.

In FIGS. 37 and 38, the cold plate includes a base plate 178 and a cover plate 179. Each of the base and cover plates 178 and 179 include a plurality of fins 180 and 181, respectively machined into the base and cover plates. Each of the base and cover plates 178 and 179 also include corresponding mating connection surfaces 182 and 183 surrounding the array of fins.

When the cover plate 179 is connected with the base plate 178 as shown in FIG. 38, the fins 181 of the cover plate 179 are offset from the fins 180 of the base plate 178 and are of the same length. Thus, in their assembled position, the fins 180 and 181 define a plurality of flow channels between them. In the preferred embodiment, the cover member 179 is connected with the base plate 178 via friction stir welding in the area 184 as a lap joint. If desired, the second or outer ends of one or more of the fins 180 can be connected to the inner surface of the cover 179 and the second or outer ends of one or more of the fins 181 can be connected with the inner surface of the base plate 178. If this connection is made, it is preferably via friction stir welding such as is shown in FIGS. 27 and 29.

FIGS. 39 and 40 illustrate a method by which an elongated hole or aperture can be formed in an article via the present invention. Specifically, the article 162 is represented in FIG. 36 as an elongated member which may be of any desired length. An opening or flow channel through the entire length of the article 162 is formed, in accordance with the present invention, by machining an elongated channel in the base material and then covering that channel with a cover plate in a hermetically sealed relationship via friction stir welding. More specifically, as shown in FIG. 40, the article 162 includes a base 164. Machined within that base 164 is a first elongated channel 165 and a pair of second elongated channels 166. These can be machined within the base 164 to any length. The respective channels 165 and 166 are then covered with a cover plate 168 and 169, respectively. The cover plates 168 and 169 are then connected to the base 164 via friction stir welding in the areas 167.

Although the description of the preferred embodiment has been quite specific, it is contemplated that various modifications could be made without deviating from the spirit of the present invention. Accordingly, it is intended that the scope of the present invention be dictated by the appended claims.

1. A cold plate comprising:
a first plate member having a second plate member receiving surface and an opposite heat transfer surface, a cooling fluid inlet and a cooling fluid outlet;
one or more fins machined in said first plate member, each of said one or more fins having a first end integrally formed with said base and a second end spaced from said first end; and
a second plate member having a first plate member engaging surface connected with said base at said cover receiving surface around the entirety of said fins, wherein said one or more fins and said second plate member form a cooling fluid flow channel from said inlet to said outlet.

2. The cold plate of claim 1 wherein said second ends of each of said one or more fins lie in a common plane.

3. The cold plate of claim 2 wherein said second ends are in substantial engagement with said second plate member.

4. The cold plate of claim 1 wherein said second ends of said one or more fins are connected with said second plate member in a sealed relationship.

5. A cold plate comprising:
a first plate member having a second plate member receiving surface portion;
one or more fluid flow channels formed in said first plate member;
a cooling fluid inlet and a cooling fluid outlet in communication with said one or more fluid flow channels;
a second plate member having a first plate member engaging surface portion connected with said first plate member receiving surface portion by friction stir welding around the entirety of said fluid flow channels.

6. The cold plate of claim 5 including one or more fins defining said one or more flow channels, each of said one or more fins including a first end integrally formed with said first plate member and a second end spaced from said first end.

7. The cold plate of claim 6 wherein said second ends of each of said fins lie in a common plane.

8. The cold plate of claim 7 wherein said second ends are in substantial engagement with said second plate member.

9. The cold plate of claim 8 wherein said second ends of said fins are connected to said second plate member via friction stir welding.

10. A method of making a cold plate comprising;
providing a first plate member of a heat conductive material;
providing one or more fins or flow channels in said first plate member; and
connecting a second plate member to a surface portion of said first plate member surrounding said one or more fins or flow channels by friction stir welding.

11. The method of claim 10 including machining said one or more fins or first plate flow channels from said member.

12. The method of claim 11 wherein each of said fins has a first end integrally formed with said base member and a second end spaced from said first end.

13. The method of claim 12 including connecting said cover to said second ends of said fins by friction stir welding.

14. The method of claim 10 including machining a second plate member receiving recess in said base, positioning said second plate member in said recess and friction stir welding said second plate member to said first plate member along edges of said second plate member and corresponding edges of said recess.

15. A method of making a cold plate comprising:
providing a first plate member of a heat conductive material;
machining one or more fins or flow channels in said first plate member, each of said fins including a first end integrally formed with said first plate member and a second end spaced from said first end; and
connecting a second plate member to a surface portion of said first plate member surrounding said one or more fins in a sealed relationship.

16. The method of claim 15 including machining said fins so that said second ends lie in a common plane.

17. The method of claim 16 including connecting said second plate member to said second ends and to said first plate member by friction stir welding.

18. A method of forming a hermetically sealed opening through an elongated article comprising:
providing an elongated article;
machining a channel in said article; and
connecting a cover to said article in the area on each side of said channel by friction stir welding.
